(19) United States
(12) Patent Application Publication
(10) Pub. No.: US 2004/0262773 A1
(43) Pub. Date: Dec. 30, 2004

(54) Chip-stacked package

(76) Inventors: Cheol Ho Joh, Seoul (KR); Qwan Ho Chung, Kyoungki-do (KR)

Correspondence Address: LADAS & PARRY LLP, 224 SOUTH MICHIGAN AVENUE, SUITE 1200, CHICAGO, IL, 60604, US

(21) Appl. No.: 10/701,326

(22) Filed: Nov. 4, 2003

(30) Foreign Application Priority Data
Jun. 25, 2003 (KR) 2003-41580

(51) Int. Cl. H01L 23/48

(52) U.S. Cl. 257/777

(57) ABSTRACT

The present invention discloses a chip-stacked package is disclosed. The chip-stacked package comprises: a doubly down-set leadframe having a down-set tip to be wire-bonded; a first semiconductor chip attached under the down-set tip of the leadframe; a first metal wire electrically connecting bonding pads of the first semiconductor chip with the down-set tip of the leadframe; a second semiconductor chip attached on the leadframe; a second metal wire electrically connecting the second semiconductor chip with the leadframe; and an epoxy molding compound encapsulating the first and second semiconductor chips, the first and second metal wires, and a portion of the leadframe while exposing the backside of the first semiconductor chip. According to the present invention, since the chip-stacked package is manufactured using the general LOC leadframe, a manufacturing process thereof can be simplified as compared to the existing chip-stacked package. Moreover, the manufacturing process of the chip-stacked package can be simplified while the manufacturing costs of the package can be reduced by virtue of the use of the inexpensive leadframe.

### BACKGROUND OF THE INVENTION

1. Field of the Invention

The present invention relates to a semiconductor package, and more particularly to a chip-stacked package using a Lead-on-Chip (LOC) leadframe.

2. Description of the Prior Art

With an increase in performance of electrical/electronic products, many technologies for mounting an increased number of packages on a board with limited size are being proposed and studied. However, since a package generally has one semiconductor chip mounted thereon, it has limitations in obtaining the desired capacity.

Meanwhile, as a method capable of increasing the capacity (i.e., integration density) of a memory chip, there is generally known a method of introducing numerous cells in a limited space. However, this method requires highly difficult processing technology, such as fine linewidth, as well as much development time. Thus, as a method capable of more easily achieving high-density integration, stacking technology was developed, and currently, studies on this technology are being actively conducted.

As used in the semiconductor art, the term “stacking” means a technology of stacking at least two chips to double memory capacity. According to this stacking technology, two 128M DRAM chips can be stacked to form a 256M DRAM, and thus, mounting density and mounting area utilization can be increased.

Methods of achieving stacked packages includes a chip stacking method of disposing two stacked chips in one package, and a package stacking method of stacking two packaged packages. However, the latter method results in an increase in the total thickness of the packages, and also has difficulty in the electrical connection between upper and lower packages due to fine pitch. For this reason, in recent stacking technology, there are many studies on the former method.

As an example of the chip-stacked packages developed according to the former method, there can be mentioned a package in which two chips are attached on a substrate having a patterned circuit in such a manner that the pad-forming side of one of the two chip faces downward and the pad-forming side of the other chip faces upward.

As another example, there can be mentioned a package which has a similar structure with the just above-mentioned package and is manufactured using an inexpensive leadframe in a substitute for the expensive substrate. The structure of this package is shown in FIG. 1.

Referring to FIG. 1, two chips 1 and 2 are attached in such a manner that the pad-forming side of one of the two chips faces downward and the pad-forming side of the other chip faces upward. Leads 3 are disposed on the pad-forming side of each of the bottom chip 1 and the top chip 2, and such leads 3 are connected with each other in groups of the opposite leads and drawn out of a package body, i.e., an epoxy molding compound 5.

And, the leads 3 are electrically connected with bonding pads 1a and 2a of the chips 1 and 2.

In current DRAM devices, there is mainly used a center pad structure where pads are arranged on the center of chips. However, stacking the chips having pads on the center thereof is more difficult than stacking edge pad chips where pads are arranged at the edge of the chips.

Furthermore, the thin small outline package (TSOP) as shown in FIG. 1 is disadvantageous in that it requires much new investment for its manufacture and also a wafer needs to be ground to very small thickness so as to make a manufacturing process complex.

### SUMMARY OF THE INVENTION

Accordingly, the present invention has been made to solve the above-mentioned problems occurring in the prior art, and an object of the present invention is to provide a chip-stacked package, which can be manufactured in a simple manner.

Another object of the present invention is to provide a chip-stacked package, which can be manufactured in a simple manner and at reduced costs.

To achieve the above-mentioned objects, the present invention provides a chip-stacked package comprising: a doubly down-set leadframe having a down-set tip to be wire-bonded; a first semiconductor chip attached under the down-set tip of the leadframe; a first metal wire electrically connecting bonding pads of the semiconductor chip with the down-set tip of the leadframe; a second semiconductor chip attached on the leadframe; a second metal wire electrically connecting the second semiconductor chip with the leadframe; and an epoxy molding compound encapsulating the first and second semiconductor chips, the first and second metal wires, and a portion of the leadframe while exposing the backside of the first semiconductor chip.

In the chip-stacked package of the present invention, the first semiconductor chip is preferably attached by means of an LOC tape. The second semiconductor chip is attached by means of adhesives. The adhesives are filled in the entire space between the second semiconductor chip and the first semiconductor chip, or interposed only between the second semiconductor chip and the leadframe. The second semiconductor chip may also be attached by means of an adhesive tape.

Furthermore, the first semiconductor chip in the chip-stacked package according to the present invention may also be attached by means of a B-stage material in a substitute for the LOC tape.

In addition, in the chip-stacked package of the present invention, the tip of the leadframe may also be designed in such a manner that it has a relatively small thickness without being down-set.

### BRIEF DESCRIPTION OF THE DRAWINGS

The above and other objects, features and advantages of the present invention will be more apparent from the following detailed description taken in conjunction with the accompanying drawings, in which:

FIG. 1 is a cross-sectional view showing a chip-stacked package according to the prior art;

FIG. 2 is a cross-sectional view showing a chip-stacked package according to a first embodiment of the present invention; and

FIGS. 3 to 6 are cross-sectional views showing chip-stacked packages according to second to fifth embodiments of the present invention.

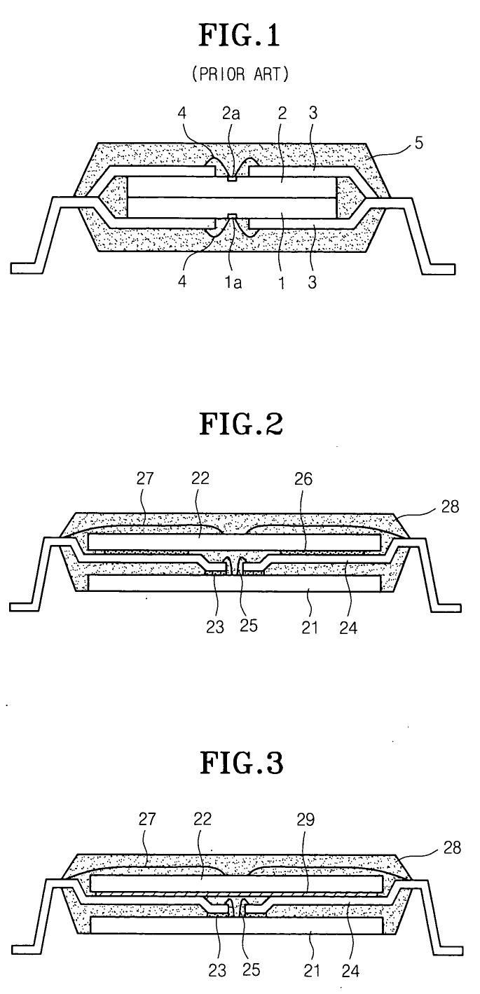

### DETAILED DESCRIPTION OF THE PREFERRED EMBODIMENTS

FIG. 2 is a cross-sectional view showing a chip-stacked package according to a first embodiment of the present invention.

Referring to FIG. 2, a first semiconductor chip 21 of a center pad type where pads are arranged on the center of the chip in two rows is attached to a down-set leadframe 24 at a pad-forming side by means of an LOC tape 23. The leadframe 24 has a down-set tip to be wire-bonded. Bonding pads (not shown) of the first semiconductor chip 21 are electrically connected with the down-set tip of the leadframe 24 by means of a first metal wire 25.

Furthermore, a second semiconductor chip 22 where pads are arranged on the chip center in two rows is attached on the leadframe 24 at a backside by means of adhesives 26. Bonding pads (not shown) of the second semiconductor chip 22 are connected with a given portion of the leadframe 24 by a second metal wire 27. The adhesives 26 are filled in the entire space between the second semiconductor chip 22 and the first semiconductor chip 21 such that internal voids, which can be formed during a molding process, are fundamentally eliminated.

And, the semiconductor chips 21 and 22, the leadframe 24 and the metal wires 25 and 27 are encapsulated with an epoxy molding compound 28 in such a manner that the leadframe 24 protrudes from the epoxy molding compound 28 by a given length. A portion of the leadframe 24 protruded from the epoxy molding compound 28 is formed into a given shape for mounting on an external circuit board. To improve a workability in a molding process and increase the heat sinking capability of the package, the epoxy molding compound 28 is formed into a shape exposing the backside of the first semiconductor chip 21.

The inventive chip-stacked package having this structure is manufactured in the following manner.

First, the first semiconductor chip 21 is attached to the doubly down-set leadframe 24 having the down-set tip by the LOC tape using a LOC die bonder. Then, bonding pads of the first semiconductor chip 21 are connected with the tip of the leadframe 24 by the first metal wire 25 through a bonding process.

Then, the adhesives 26 are applied on the surface of the first semiconductor chip 21 and the inner leads of the leadframe 24. Next, the second semiconductor chip 22 is stuck on the adhesives 26 followed by the curing of the adhesives 26. Thereafter, bonding pads of the second semiconductor chip 22 are connected with a given portion of the leadframe 24 by the second metal wire 27 through a wire bonding process. Preferably, the leadframe 24 is plated with silver (Ag), gold (Au) or palladium (Pd) for wire stitch bonding.

Then, the members other than the backside of the first semiconductor chip 21 are encapsulated with the epoxy molding compound 28.

Subsequently, conventional assembly processes, i.e., laser marking, trimming, plating and forming, are performed to manufacture the chip-stacked package.

Since the chip-stacked package of the present invention is manufactured using the existing LOC leadframe structure, the existing TSOP manufacture facilities can be employed for the manufacture of the chip-stacked package as they are. Thus, it can be manufactured in a simplified manner and at reduced costs as compared to the currently well-known center pad chip-stacked package.

Furthermore, since the backside of the first semiconductor chip is exposed to the environment outside the epoxy molding compound, the heat sinking capacity of high-speed operation devices can be improved, and also the likelihood of chip tilt and void formation in a molding process can be fundamentally eliminated.

FIGS. 3 to 6 are cross-sectional views showing chip-stacked packages according to other embodiments of the present invention. A description of FIGS. 3 to 6 will be made for different particulars from FIG. 2.

In a chip-stacked package according to a second embodiment of the present invention as shown in FIG. 3, the adhesives 26 for attaching the second semiconductor chip 22 on the leadframe 24 is interposed only between the second semiconductor chip 22 and the leadframe 24. In this embodiment, the amount of use of adhesives can be reduced to increase productivity and to reduce manufacturing costs.

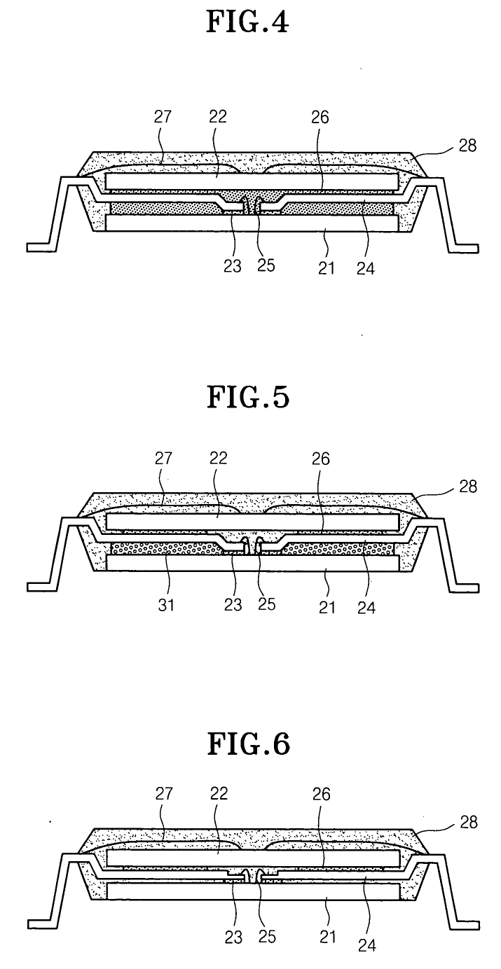

In a chip-stacked package according to a third embodiment of the present invention as shown in FIG. 4, an adhesive tape 29 in a substitute for adhesives is used for attaching the second semiconductor chip 22 on the leadframe 21. In this embodiment, adhesive application and curing procedures are not required, and thus, there is an advantage in that a manufacturing process of the package becomes simple.

In a chip-stacked package according to a fourth embodiment of the present invention as shown in FIG. 5, a B-stage material 31 is applied on the first semiconductor chip 21, and then, the first semiconductor chip 21 is attached to the leadframe 24 by the applied B-stage material 31. In this embodiment, an expensive LOC tape is not used for attaching the first semiconductor chip 21 to the leadframe 24, and thus, manufacturing costs can be reduced.

In a chip-stacked package according to a fifth embodiment of the present invention as shown in FIG. 6, the inner lead tip of the leadframe 24 is designed in such a manner that it has a relatively small thickness by half etching or coining, etc., without being down-set.

Although not shown in the figures, in another embodiment of the present invention, a protective tape may be attached to the backside of the first semiconductor chip, which is exposed to the environment outside the epoxy molding compound. In this case, the first semiconductor chip can be protected from physical damage and static electricity. In still another embodiment of the present invention, the chip-stacked package may also be manufactured in such a manner that the backside of the first semiconductor chip is not exposed to the environment outside the epoxy molding compound.

As described above, according to the present invention, since the chip-stacked package is manufactured using the general LOC leadframe, a manufacturing process thereof can be simplified as compared to the existing chip-stacked package. Moreover, according to the present invention, the manufacturing process of the chip-stacked package can be simplified while the manufacturing costs of the package can be reduced by virtue of the use of the inexpensive leadframe. Furthermore, according to the present invention, the backside of the first semiconductor chip is exposed to the environment outside the epoxy molding compound, so that problems that can occur during a molding process can be fundamentally eliminated and also the heat sinking capacity of the package can be improved. In addition, the larger the chip size, stacking operations become easier. For this reason, if a large-sized chip is applied, the ratio of the chip size to the package size can be increased to the level of a chip size package.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A chip-stacked package comprising:
a doubly down-set leadframe having a down-set tip to be wire-bonded;
a first semiconductor chip attached under the down-set tip of the leadframe;
a first metal wire electrically connecting bonding pads of the first semiconductor chip with the down-set tip of the leadframe;
a second semiconductor chip attached on the leadframe;
a second metal wire electrically connecting the second semiconductor chip with the leadframe; and
an epoxy molding compound encapsulating the first and second semiconductor chips, the first and second metal wires, and a portion of the leadframe while exposing the backside of the first semiconductor chip.

2. The chip-stacked package of claim 1, wherein the first semiconductor chip is attached by means of an LOC tape.

3. The chip-stacked package of claim 1, wherein the second semiconductor chip is attached by means of adhesives.

4. The chip-stacked package of claim 3, wherein the adhesives are filled in the entire space between the second semiconductor chip and the first semiconductor chip.

5. The chip-stacked package of claim 3, wherein the adhesives are interposed only between the second semiconductor chip and the leadframe.

6. The chip-stacked package of claim 1, wherein the second semiconductor chip is attached by means of an adhesive tape.

7. A chip-stacked package comprising:
a doubly down-set leadframe having a down-set tip to be wire-bonded;
a first semiconductor chip attached under the leadframe by means of a B-stage material;
a first metal wire electrically connecting bonding pads of the first semiconductor chip with the tip of the leadframe;
a second semiconductor chip attached on the leadframe by means of adhesives;
a second metal wire electrically connecting the second semiconductor chip with the leadframe; and
an epoxy molding compound encapsulating the first and second semiconductor chips, the first and second metal wires, and a portion of the leadframe while exposing the backside of the first semiconductor chip.

8. A chip-stacked package comprising:
a down-set leadframe having a tip to be wire-bonded, the tip being designed in such a manner as to have a relatively small thickness;
a first semiconductor chip attached under the tip of the leadframe;
a first metal wire electrically connecting bonding pads of the first semiconductor chip with the tip of the leadframe;
a second semiconductor chip attached on the leadframe;
a second metal wire electrically connecting the second semiconductor chip with the leadframe; and
an epoxy molding compound encapsulating the first and second semiconductor chips, the first and second metal wires, and a portion of the leadframe while exposing the backside of the first semiconductor chip.
